(19) United States
(12) Patent Application Publication
(10) Pub. No.: US 2022/0019140 A1
(43) Pub. Date: Jan. 20, 2022

(54) METHODS OF MANUFACTURING A TEXTURED SURFACE USING SOLUBLE TEMPLATES

(71) Applicant: Sharklet Technologies, Inc., Aurora, CO (US)

(72) Inventors: MiKayla Maye Henry, Aurora, CO (US); Kevin Lee Ballard, Aurora, CO (US)

(21) Appl. No.: 17/296,289

(22) PCT Filed: Nov. 26, 2019
(86) PCT No.: PCT/US2019/063222

§ 371 Date: May 24, 2021

Related U.S. Application Data
(60) Provisional application No. 62/772,853, filed on Nov. 29, 2018.

(51) Int. Cl. G03F 7/00

(52) U.S. Cl. CPC G03F 7/0002

(57) ABSTRACT

Disclosed herein is a method of using a template for texturing a surface comprising contacting an article surface with a template; where the template comprises a soluble polymer that has a texture disposed thereon; where the texture comprises a pattern comprising a first plurality of spaced features; the spaced features arranged in a plurality of groupings; the spaced features within a grouping being spaced apart at an average distance of about 1 nanometer to about 500 micrometers; each feature having a surface that is substantially parallel to a surface on a neighboring feature; each feature being separated from its neighboring feature; and wherein the groupings of features being arranged with respect to one another so as to define a tortuous pathway; where the template in in the form of a free-standing film.

### CROSS REFERENCE TO RELATED APPLICATIONS

This application claims the benefit of U.S. Application No. 62/772,853 filed on Nov. 29, 2018, which is incorporated herein by reference in its entirety.

### BACKGROUND

This disclosure relates to methods of manufacturing textured surfaces from soluble templates.

Texturing of surfaces has been developed for controlling bioadhesion, for flow control of fluids in contact with the textured surface, and for a variety of other reasons. FIG. 1 depicts a surface texture 100 that can be used for controlling bioadhesion as well as for flow control. The texture comprises a plurality of features 111 that are arranged to have edges 130 that parallel to each other in at least one direction. As can be seen in the FIG. 1, the features are arranged in patterns (encompassed by the dotted lines) 102 that are repeated across the textured surface.

FIGS. 2 and 3 depict another textured surface 100 that contains repeating patterns where some of the patterns are oriented at a different angles when compared with some of the other patterns. In the FIG. 2, the patterns in the 4 quadrants (1, 2, 3 and 4 respectively) are oriented different directions with respect to each other. The axis AA′ indicates the axis of orientation of the pattern in a first quadrant, while the pattern BB′ indicates the orientation of the pattern in a neighboring quadrant. From the FIG. 2, it may be seen that the axis AA′ oriented orthogonally to the axis BB′. The patterns in quadrants 1 and 3 are therefore oriented at right angles with respect to the patterns in the quadrants 2 and 4. This orientation of the patterns is used to control fluid flow on a surface in a particular direction because the length of the tortuous path that a fluid has to flow in order to get across the pattern is increased tremendously. By orienting the patterns in mutually perpendicular directions, the fluid flow in one direction is obstructed by the patterns in a neighboring quadrant thus minimizing fluid flow across the pattern.

FIG. 3 also shows a textured surface 100 that comprises a plurality of patterns that are oriented with respect to one another. In the FIG. 3, there are three different orientations of the features in the patterns, P, M and N respectively. These orientations lie along the axes AA′, XX′ and YY′ respectively. The long range order seen along the axes AA′, XX′ and YY′ can be advantageously used to control and direct flow of fluid by varying the pattern orientation along these axes.

FIGS. 4A-4D also depict a variety of structures that can be used to control bio-adhesion and to effect flow control. Manufacturing the textured surfaces depicted in the FIGS. 1, 2, 3 and 4A-4D is expensive because it often involves the use of expensive and heavy injection molding equipment. Special dies (that contain the texture) need to be manufactured for use in the injection molding equipment. Limitations in die size restrict the surface area of an article that can be textured in single manufacturing operation. In addition, it is difficult to manufacture dies that can texture complicated and difficult-to-reach parts of an articles. Because injection molding equipment and the dies that are used with it are heavy in weight and difficult to manufacture, it is desirable to find lighter and less expensive means of texturing surfaces. It is also desirable to develop manufacturing templates that can be transported to any location and be used at that location to texture a desired surface.

### SUMMARY

Disclosed herein is a method of using a template for texturing a surface comprising contacting an article surface with a template; where the template comprises a soluble polymer that has a texture disposed thereon; where the texture comprises a pattern comprising a first plurality of spaced features; the spaced features arranged in a plurality of groupings; the spaced features within a grouping being spaced apart at an average distance of about 1 nanometer to about 500 micrometers; each feature having a surface that is substantially parallel to a surface on a neighboring feature; each feature being separated from its neighboring feature; and wherein the groupings of features being arranged with respect to one another so as to define a tortuous pathway; where the template in in the form of a free-standing film that has a maximum thickness of 1.5 millimeters and a minimum thickness that is no greater than 40 percent of the maximum thickness; where the surface area of the textured surface is at least greater than 10 cm²; and washing the article surface with a solvent that dissolves the template.

Disclosed herein is a method comprising disposing a liquid coating upon a substrate; disposing upon the coating a template; where the template comprises a soluble polymer that has a texture disposed thereon; where the texture comprises a pattern comprising a first plurality of spaced features; the spaced features arranged in a plurality of groupings; the spaced features within a grouping being spaced apart at an average distance of about 1 nanometer to about 500 micrometers; each feature having a surface that is substantially parallel to a surface on a neighboring feature; each feature being separated from its neighboring feature; and wherein the groupings of features being arranged with respect to one another so as to define a tortuous pathway; where the template is in the form of a free-standing film that has a maximum thickness of 1.5 millimeters and a minimum thickness that is no greater than 40 percent of the maximum thickness; where the surface area of the textured surface is at least greater than 10 cm²; solidifying the coating; and dissolving the template.

### BRIEF DESCRIPTION OF THE FIGURES

FIG. 1 depicts patterns on a textured surface in which the features are arranged in a repeating fashion across a surface;

FIG. 2 depicts another textured surface that contains repeating patterns where some of the patterns are oriented at a different angles when compared with some of the other patterns;

FIG. 3 depicts another textured surface that contains repeating patterns where some of the patterns are oriented at a different angles when compared with some of the other patterns;

FIG. 4A depicts one arrangement of features on a surface that can be used to control bioadhesion;

FIG. 4B depicts another arrangement of features on a surface that can be used to control bioadhesion;

FIG. 4C depicts another arrangement of features on a surface that can be used to control bioadhesion;

FIG. 4D depicts another arrangement of features on a surface that can be used to control bioadhesion;

FIG. 5 depicts the basic repeat unit that forms the texture shown in the FIG. 4A;

FIG. 6 depicts an exemplary embodiment of a single template texturing a single article surface; and

FIG. 7 depicts an exemplary embodiment of a single template simultaneously texturing surfaces of multiple articles.

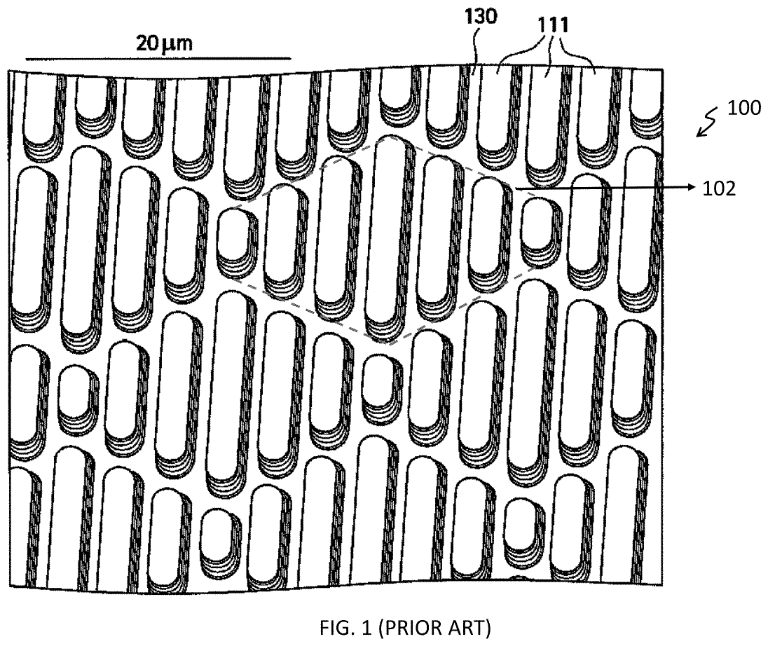

### DETAILED DESCRIPTION

Disclosed herein is a method for generating textured surfaces (also referred to herein as patterned surfaces) on a variety of articles using a template that is a free-standing film. In addition to being free-standing, the template is flexible and soluble. The template contains a pattern that is a mirror image of the pattern that is to be disposed on a desired surface. One surface or both opposing surfaces of the free-standing film may contain a pattern that is used to texture desired surfaces. The template may also be used to deposit certain materials on the surface of textured article.

The template may be used to texture surfaces in a batch processes or in continuous processes. The template is pressed against a surface that is to be textured. The texturing may be conducted in an industrial manufacturing environment or in an environment that lies outside a manufacturing facility.

After texturing the surface, the template is removed by dissolution leaving behind a textured surface on the article. The solubility of the template permits the template to be dissolved or washed off of the patterned surface once the surface has been textured. The template is therefore a disposable template. The template may also be degraded and dissolved in order to remove it from a textured surface.

Surfaces that are textured include coated or painted surfaces. The template is pressed against the coating or paint that is then solidified via curing, drying, or the like. After the coating or paint solidifies, the template is washed off. The coating or paint that is textured has a thickness of 2 to 100 micrometers, preferably 3 to 75 micrometers, and more preferably 5 to 50 micrometers prior to being textured with the template.

As noted above, this mode of texturing permits the texturing to be performed outside of a manufacturing facility. For example much like wallpapering, one can manually laminate a painted surface with the template, and then wash the surface off after everything dries and cures. This is conducted outside of a manufacturing environment in some cases (such as a maintenance department in a hospital or at a construction site).

In one embodiment, the texture is transferred from the template to an article surface via batch processes such as compression molding, vacuum forming, injection molding, blow molding, or the like. Batch production is a technique used in manufacturing, in which the object in question is created stage by stage over one or more workstations. Because the template comprises a polymer, it is light in weight and as a result may be easily placed in a mold or a die and used to texture the article manufactured in the mold or die. The lightweight aspects of the template enables it to be rapidly replaced in a mold or die in a rapid batch manufacturing processes.

In another embodiment, the texture is transferred from the template to an article surface in a continuous process. Continuous production is a flow production method used to manufacture, produce, or process materials without interruption. Continuous production is called a continuous process or a continuous flow process because the materials, either dry bulk or fluids that are being processed are continuously in motion, undergoing chemical reactions or subject to mechanical or heat treatment. An example of a continuous process includes embossing. The embossing is conducted in a hot press or on a roll mill. The texture may be simultaneously transferred on to two of more surfaces at one time if desired.

The template is a free-standing film that is preferably manufactured from a material that is easily soluble in a solvent. A free-standing film is one that is not supported on a substrate and that can be independently transported for use at a location other than the site of its manufacture. The solvent may be an organic solvent (i.e., a non-aqueous solvent) or an aqueous solvent and may be used to dissolve the template or to wash away the template after the texturing is completed. The template preferably comprises an organic polymer of a molecular weight that renders it soluble in a liquid solvent at room temperature.

The organic polymer used to manufacture the template may comprise a thermoplastic polymer, a blend of thermoplastic polymers, a thermosetting polymer, a blend of thermosetting polymers or a blend of thermoplastic polymers with thermosetting polymers. The organic polymer may also be a blend of polymers, copolymers, terpolymers, or combinations comprising at least one of the foregoing organic polymers. The organic polymer can also be an oligomer, a homopolymer, a copolymer, a block copolymer, an alternating block copolymer, a random polymer, a random copolymer, a random block copolymer, a graft copolymer, a star block copolymer, a dendrimer, a polyelectrolyte (polymers that have some repeat groups that contain electrolytes), a polyampholyte (a polyelectrolyte having both cationic and anionic repeat groups), an ionomer, or the like, or a combination comprising at last one of the foregoing organic polymers. The organic polymers have number average molecular weights greater than 10,000 grams per mole, preferably greater than 20,000 g/mole and more preferably greater than 50,000 g/mole.

A preferred polymer for use as a template is a linear thermoplastic polymer or a lightly crosslinked polymer that is amorphous. The polymer may or may not be compatible with water. The polymer preferably has a dissolution rate of 0.5 to 10 grams per minute in an effective solvent at room temperature.

Examples of thermoplastic polymers that can be used in the template include polyacetals, poly acrylics, polycarbonates, polyalkyds, polystyrenes, polyolefins, polyesters, polyamides, polyaramides, polyamideimides, polyarylates, polyurethanes, epoxies, phenolics, silicones, polyarylsulfones, polyethersulfones, polyphenylene sulfides, polysulfones, polyimides, polyetherimides, polytetrafluoroethylenes, polyetherketones, polyether ether ketones, polyether ketone ketones, polybenzoxazoles, polyoxadiazoles, polybenzothiazinophenothiazines, polybenzothiazoles, polypyrazinoquinoxalines, polypyromellitimides, polyquinoxalines, polybenzimidazoles, polyoxindoles, polyoxoisoindolines, polydioxoisoindolines, polytriazines, polypyridazines, polypiperazines, polypyridines, polypiperidines, polytriazoles, polypyrazoles, polycarboranes, polyoxabicyclononanes, polydibenzofurans, polyphthalides, polyacetals, poly anhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, poly sulfonamides, polyureas, polyphosphazenes, polysiloxanes, polypropylenes, polyethylenes, polyethylene terephthalates, polyvinylidene fluorides, polysiloxanes, polyhexamethylcellulose, polyhexaethylcellulose, polyethyleneimines, polyvinylpyrrolidone, polyamidoamines or the like, or a combination thereof.

Examples of polyelectrolytes suitable for use in the template include are polystyrene sulfonic acid, polyacrylic acid, pectin, carrageenan, alginates, carboxymethylcellulose, polyvinylpyrrolidone, or the like, or a combination thereof.

Examples of thermosetting polymers suitable for use in the template include epoxy polymers, unsaturated polyester polymers, polyimide polymers, bismaleimide polymers, bismaleimide triazine polymers, cyanate ester polymers, vinyl polymers, benzoxazine polymers, benzocyclobutene polymers, acrylics, alkyds, phenol-formaldehyde polymers, novolacs, resoles, melamine-formaldehyde polymers, urea-formaldehyde polymers, hydroxymethylfurans, isocyanates, diallyl phthalate, triallyl cyanurate, triallyl isocyanurate, unsaturated polyesterimides, or the like, or a combination thereof.

Examples of blends of thermoplastic polymers include acrylonitrile-butadiene-styrene/nylon, polycarbonate/acrylonitrile-butadiene-styrene, acrylonitrile butadiene styrene/polyvinyl chloride, polyphenylene ether/polystyrene, polyphenylene ether/nylon, polysulfone/acrylonitrile-butadiene-styrene, polycarbonate/thermoplastic urethane, polycarbonate/polyethylene terephthalate, polycarbonate/polybutylene terephthalate, thermoplastic elastomer alloys, nylon/elastomers, polyester/elastomers, polyethylene terephthalate/polybutylene terephthalate, acetal/elastomer, styrene-maleic anhydride/acrylonitrile-butadiene-styrene, polyether etherketone/polyethersulfone, polyether etherketone/polyetherimide polyethylene/nylon, polyethylene/polyacetal, or the like.

Polymers that can be used in the template also include biodegradable materials. Suitable examples of biodegradable polymers are as polylactic-glycolic acid (PLGA), poly-caprolactone (PCL), copolymers of polylactic-glycolic acid and poly-caprolactone (PCL-PLGA copolymer), polyhydroxy-butyrate-valerate (PHBV), polyorthoester (POE), polyethylene oxide-butylene terephthalate (PEO-PBTP), poly-D,L-lactic acid-p-dioxanone-polyethylene glycol block copolymer (PLA-DX-PEG), or the like, or a combination thereof.

Preferred polymers are those that can be dissolved in water or in solvents that comprise water. Exemplary water soluble polymers are polyvinylalcohol, polyacrylamide, polyhexamethylcellulose, polyhexaethylcellulose, polyethyleneimine, polyvinylpyrrolidone, polyamidoamine, polyethylene glycol, or a combination thereof. Copolymers of the foregoing water soluble polymers may also be used. When a water soluble copolymer is used, the other polymer that is copolymerized with the water soluble polymer does not have to be water soluble. It is desirable however, that the copolymer is soluble in water even if a portion of it is not water soluble.

A preferred polymer for use as a template is a linear thermoplastic polymer. A suitable example of a linear thermoplastic polymer is polyvinylalcohol.

The template may contain a variety of additives. Additives include reinforcing fillers, antiozonants, antioxidants, mold release agents, antiblock agents, anti-slip agents, electrically conducting fillers, or the like, or a combination thereof.

It is desirable for the template to be flexible so that it can be transported easily. In an embodiment, the template can be rolled on to a central shaft and transported for use elsewhere. The template has a thickness “t” of 10 nanometers to 0.5 millimeters, preferably 100 nanometers to 1 millimeter, and preferably 200 nanometers to 0.5 millimeters. In a preferred embodiment, the thickness of the template may be 0.02 to 0.25 millimeters.

The template is textured using an embossing technique or a casting process. In the embossing technique, a molten polymer (used for manufacturing the template) is disposed on a first surface of a platen. An opposing textured second surface is then pressed against the molten polymer. The texture is transferred to the polymer. After cooling, the polymer is removed from the platens and used to impart the texture contained thereon to another polymer surface. In an embodiment, the opposing surfaces of the template may both be textured in a single operation. This is accomplished by depressing the molten polymer between two opposing surfaces of a platen, both of which are textured.

In an embodiment, the opposing surfaces of the template can contain the same texture. In another embodiment, the opposing surfaces of the template can contain different texture. The texture on one surface of the template can be rotated to be inclined at a different angle from the texture on an opposing surface of the template.

In yet another embodiment, involving hot embossing, a film that is to be used as a template is disposed on a first surface of a platen. The film is below its melting point. A second surface having the desired texture disposed thereon then contacts the film under pressure. The second surface may be at an elevated temperature. The first surface may also be maintained at an elevated temperature. The elevated temperature of the first surface may be the same as, or alternatively may be different from the elevated temperature of the second surface. Upon being contacted by the textured second surface the film is embossed and now contains a mirror image of the texture contained on the second surface of the platen. The template may then be used to impart the texture contained thereon to other surfaces. This method may also be used to texture opposing surfaces of the template.

The pressure applied by the second template to the film lying of the first template is 5 to 150 pounds per square inch, preferably 10 to 100 pounds per square inch, and more preferably 15 to 80 pounds per square inch. A preferred temperature is from room temperature (23° C.) to 300° C., preferably 40 to 150° C., and more preferably 50 to 125° C.

In another embodiment, the texture is manufactured by casting. In the casting process, a solution containing a solvent and the polymer used to manufacture the template is disposed on a surface that has the desired texture. The textured surface is heated to evaporate the solvent and to promote solidification of the polymer. A vacuum may be used to assist in the solidification of the polymer. The solidified polymer now contains a mirror image of the textured surface and can be used as a template.

It is to be noted that the two platens may be rollers in a roll mill. One roller serves as the first platen while the opposing roller serves as the second platen. One or both of the rollers may be textured. As the rollers contact the soluble polymer, the surface(s) of the soluble polymer may be textured.

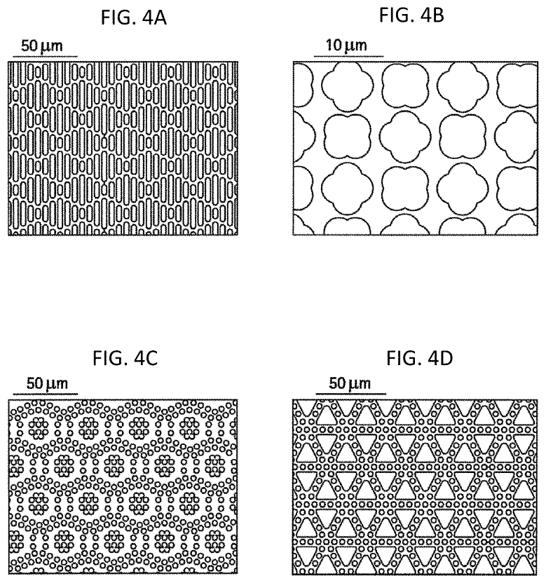

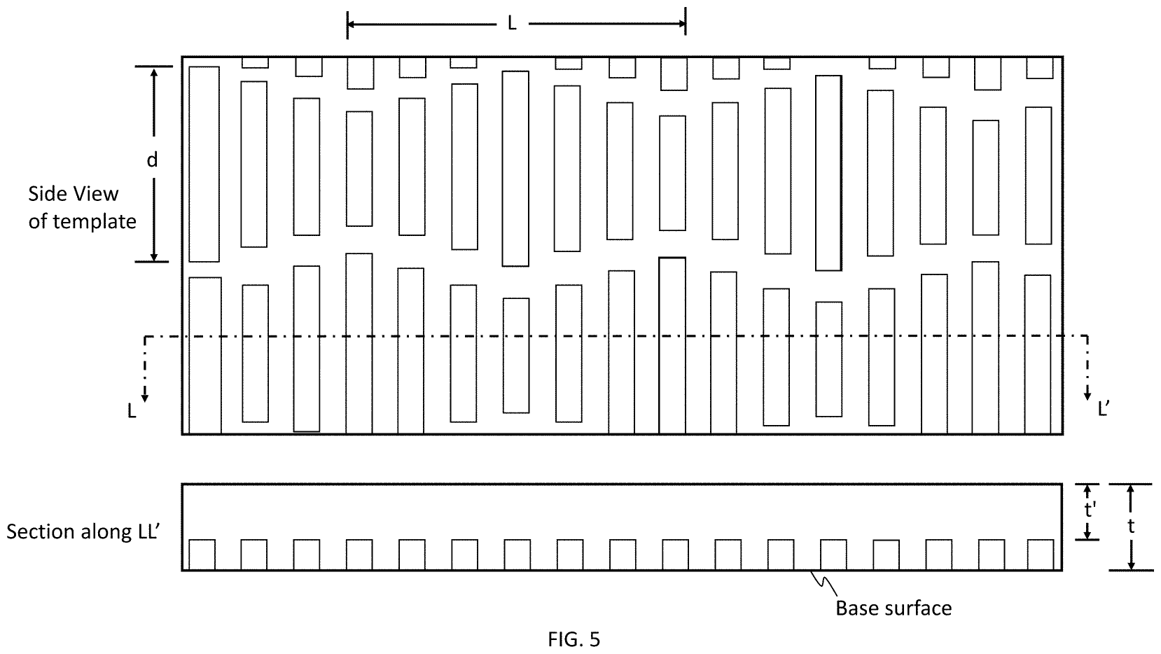

The template along with the texture imparted to the template is further detailed below. FIG. 5 depicts the basic repeat unit that forms the texture shown in the FIG. 4A. FIG. 5 is used to detail the template and represents only one embodiment of the texture that can be transferred via a template. Other templates containing other textural designs may also be used in the manner described herein. FIG. 5 depicts a side view and a cross-sectional view of the section LL′ of the template.

The basic repeat unit comprises a plurality of elongated spaced features that are parallel to each other, but that when aligned as seen in the FIG. 4A or 5, define a sinusoidal pathway when viewed in a first direction. The pathway (in the template) when viewed in the first direction may also be represented by a spline function. In one embodiment, when viewed in a second direction, the pathway between the features may be non-linear and non-sinusoidal. In other words, the pathway can be non-linear and aperiodic. In another embodiment, the pathway between the features may be linear but of a varying thickness. The plurality of spaced features may be projected outwards from a surface or projected into the surface. The features in the FIG. 5 are projected into the surface of the template.

In one embodiment, the plurality of spaced features may have the same chemical composition as the surface. In another embodiment, the plurality of spaced features may have a different chemical composition from the surface. In other words, the features may be bonded to the surface of the template to adjust the surface energy of the features on the textured surface (that is manufactured using the template). In another embodiment, the features and the surface of the template may be monolithic (i.e., they form one undivided article).

In an embodiment, the surface texture comprises a plurality of identical patterns; each pattern being defined by a plurality of spaced apart features attached to or projected into the first surface where at least one spaced apart feature has a dimension “d” of about 1 nanometer to about 1 millimeter, preferably 5 nanometers to 500 micrometers, and more preferably 100 nanometers to 50 micrometers.

In another embodiment, the average periodicity between the spaced features can be about 1 nanometer to about 500 micrometers. In one embodiment, the periodicity between the spaced features can be about 2, 5, 10, 20, 50, 100 or 200 nanometers. In another embodiment, the average periodicity between the spaced features can be about 2, 5, 10, 20, 50, 100 or 200 nanometers. In another embodiment, the periodicity can be about 0.1, 0.2, 0.5, 1, 5, 10, 20, 50, 100, 200, 300, 400 or 450 micrometers. In yet another embodiment, the average periodicity can be about 0.1, 0.2, 0.5, 1, 5, 10, 20, 50, 100, 200, 300, 400 or 450 micrometers.

In one embodiment, the spaced features can have dimensions of 1 nanometer to 500 micrometers, specifically about 10 nanometers to about 200 micrometers, and more specifically about 50 nanometers to about 100 micrometers.

In another embodiment, each pattern has at least one or more neighboring patterns that have a different size or shape. In other words, a first pattern can have a second neighboring pattern that while comprising the same features as the first pattern can have a different shape from the first pattern. In yet another embodiment, each pattern has at least two or more neighboring patterns that have a different size or shape. In yet another embodiment, each pattern has at least three or more neighboring patterns that have a different size or shape. In yet another embodiment, each pattern has at least four or more neighboring patterns that have a different size or shape.

In one embodiment, each feature of a pattern has at least one neighboring feature that has a different geometry (e.g., size or shape). A feature of a pattern is a single element. Each feature of a pattern has at least 2, 3, 4, 5, or 6 neighboring features that have a different geometry from the feature. In one embodiment, there are at least 2 or more different features that form the pattern. In another embodiment, there are at least 3 or more different features that form the pattern. In yet another embodiment, there are at least 4 or more different features that form the pattern. In yet another embodiment, there are at least 5 or more different features that form the pattern.

In another embodiment, at least two identical features of the pattern have at least one neighboring feature that has a different geometry (e.g., size or shape). A feature of a pattern is a single element. In one embodiment, two identical features of the pattern have at least 2, 3, 4, 5, or 6 neighboring features that have a different geometry from the identical features. In another embodiment, three identical features of the pattern have at least 2, 3, 4, 5, or 6 neighboring features that have a different geometry from the identical features.

In an embodiment, the plurality of spaced features (which may be uniformly or non-uniformly spaced) in a pattern have a total length “L” of 1 to 60 micrometers, preferably 10 to 50 micrometers, and more preferably 15 to 40 micrometers.

In an embodiment, the template has a total thickness “t” of 10 nanometers to 1.5 millimeters, preferably 100 nanometers to 1.0 millimeter, and more preferably 200 nanometers to 0.5 millimeters. The thickness t′ represents the thinnest section of the template and provides a measure of the ease with which the template can be washed off of a surface that it has been used to texture. In the FIG. 5, the thickness t′ is the thickness of the template minus the depth of the protrusion of a feature from the base surface. Thinner templates are flexible and can therefore be used to texture convoluted surfaces.

The thickness t′ (which may be referred to as a partial thickness) is less than thickness t and generally does not exceed a maximum value of 80% of the total thickness t. In an embodiment, the thickness t′ generally does not exceed a maximum value of 60% of the total thickness t. In yet another embodiment, the thickness t′ generally does not exceed a maximum value of 40% of the total thickness t. The template has thickness t′ of 4 nanometers to 0.6 millimeters, preferably 40 nanometers to 0.4 millimeters, and more preferably 80 nanometers to 0.2 millimeters.

The texture on the template may be detailed by nomenclature. The nomenclature is expressed by the following formula (1):

−A₁SKA₂×A₃ (1)

where the sign that precedes A₁ indicates whether the texture protrudes out of or into the base surface of the template. A positive sign (+) indicates that the texture protrudes out of the base surface, while a negative sign (−) indicates that the texture protrudes into the base surface. The term A₁ represents the height or depth of the texture above or below the base surface in micrometers, while A₂ represents the width of each feature in the pattern in micrometers while A₃ represents the spacing between the features in the pattern in micrometers. The term SK represents the SHARKLET® pattern texture depicted and described in U.S. Pat. No. 7,143,709 B2 to Brennan et al., and patent application having Ser. No. 12/550,870 to Brennan et al. The Sharklet® pattern texture is the texture shown in the FIGS. 4A and 5.

A numerical example of the nomenclature is as follows. The nomenclature (e.g., +1.7SK2x2) should be deciphered as follows: The +1.7 indicates the height of the texture in micrometers above the base surface while the SK refers to a Sharklet pattern depicted and described in U.S. Pat. No. 7,143,709 B2 to Brennan et al., and patent application having Ser. No. 12/550,870 to Brennan et al. A negative sign (−) preceding the 1.7 would indicate that the texture is below the base surface (protrudes into the base surface). The first 2 in SK2x2 stands for the width of each feature (in micrometers) in the pattern while the second 2 stands for the spacing between the features (in micrometers) in the pattern.

The template has a total surface area (length×width) that is greater than 10 square centimeter (cm²), preferably greater than 20 cm², preferably greater than 100 cm², more preferably greater than 1 square meter (m²), more preferably greater than 10 m², and more preferably greater than 100 m². Large sections of template can be rolled up onto a shaft and transported for use elsewhere.

In an embodiment, the plurality of spaced features has a similar chemical composition to the surface. In another embodiment, the plurality of spaced features has a different chemical composition from the composition of the surface. The plurality of spaced features is applied to the surface in the form of a coating. The patterns on the article have an engineered roughness index (ERI) of about 2 to about 30, preferably 5 to 25. The engineered roughness index is shown in the equation (1) below.

ERI=r×d_{f}/f_{d} (1)

where r is the Wenzel roughness, d_{f} is the degrees freedom and f_{d} is the depressed area fraction. The degrees of freedom is the number of pathways a spore or bacteria could travel if were traveling down a given channel. The ERI is defined in U.S. Pat. No. 7,650,848 to Brennan et al., the entire contents of which are hereby incorporated by reference.

The plurality of features (on the template) each have at least one neighboring feature having a substantially different size or geometry, wherein each pattern has at least one feature which is identical to a feature of a neighboring pattern and shares that feature with the neighboring pattern. The average spacing between adjacent spaced apart features is about 1 nanometer to about 1 millimeter in at least a portion of the first surface and/or the second surface (which is opposed to the first surface and in contact with it). The plurality of spaced apart features are represented by a periodic function since the features in the patterns are equidistant from each other. It is to be noted that there are no two individual neighboring features that are identical in size to each other.

As noted above, the pattern in the template is separated from a neighboring pattern by a tortuous pathway. The tortuous pathway may be represented by a periodic function. The periodic functions may be different for each tortuous pathway. In one embodiment, the patterns can be separated from one another by tortuous pathways that can be represented by two or more periodic functions. The periodic functions may comprise a sinusoidal wave. In an exemplary embodiment, the periodic function may comprise two or more sinusoidal waves.

In another embodiment, when a plurality of different tortuous pathways are represented by a plurality of periodic functions respectively, the respective periodic functions may be separated by a fixed phase difference. In yet another embodiment, when a plurality of different tortuous pathways are represented by a plurality of periodic functions respectively, the respective periodic functions may be separated by a variable phase difference.

In one embodiment, the plurality of spaced apart features have a substantially planar top surface. In another embodiment, a multi-element plateau layer can be disposed on a portion of the surface, wherein a spacing distance between elements of said plateau layer provide a second feature spacing; the second feature spacing being substantially different when compared to the first feature spacing.

In one embodiment, a sum of a number of features shared by two neighboring groupings is equal to an odd number. In another embodiment, a sum of a number of features shared by two neighboring groupings is equal to an even number.

As can be seen in the FIGS. 4A and 5, the tortuous pathway exists substantially between pluralities of groupings of such features. The groupings of features is also called a pattern. The pattern may also be viewed as a repeat unit, since it repeats itself across the surface of the template. As can be seen in the FIG. 4A, an occasional feature may lie in the otherwise tortuous pathway. In one embodiment, a tangent to the tortuous pathway will always intersect a single separated feature of the pattern. In one embodiment, a frequency of intersection between the tangent to the tortuous pathway and the spaced feature is periodic. In another embodiment, a frequency of intersection between a tangent to the tortuous pathway and a spaced feature is aperiodic. In another embodiment, a frequency of intersection between a tangent to the tortuous pathway and a shared feature is periodic. In another embodiment, a frequency of intersection between a tangent to the tortuous pathway and the shared spaced feature is aperiodic.

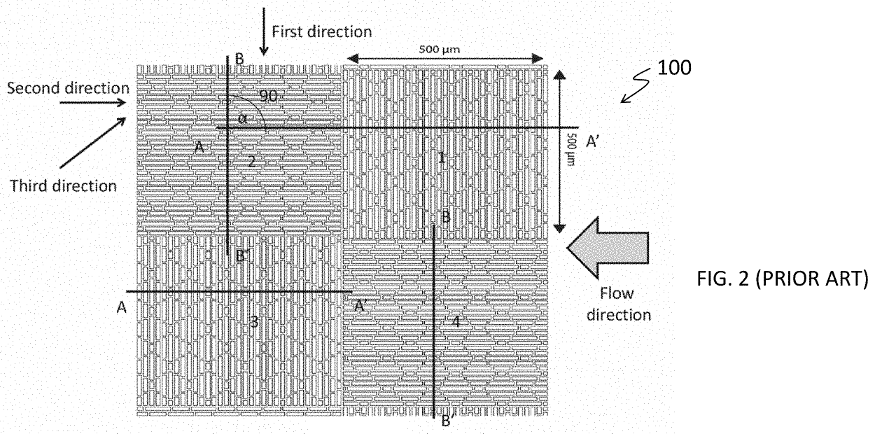

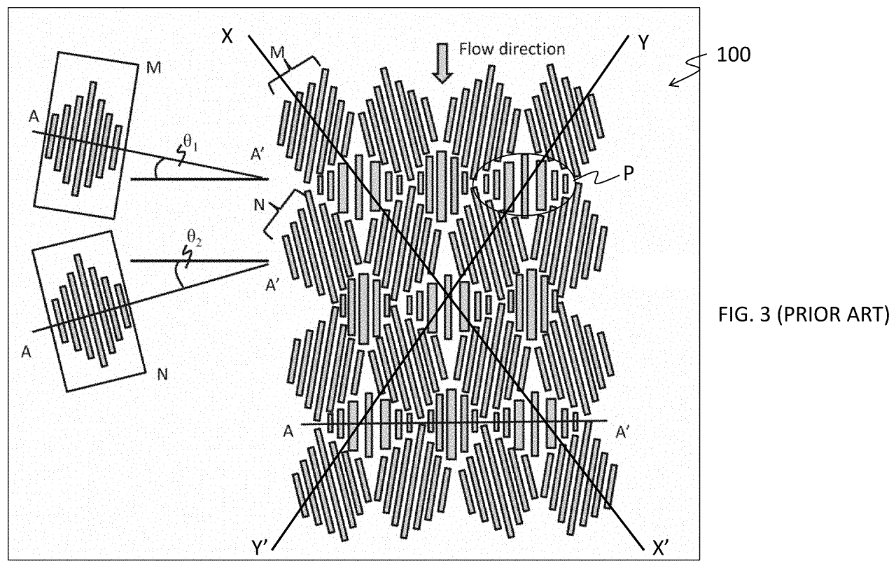

It is generally desirable for the groupings of features to comprise at least one repeat unit and to share at least one common feature. For example, in the FIG. 4A, the groupings of feature form a repeat unit that has a diamond shape. It can also be seen that the smallest feature in each repeat unit is shared by two adjacent repeat units or by two adjacent groups of features. The sharing of the feature by two or more groups of patterns results in the formation of the tortuous pathway. Similarly the FIGS. 2A and 2B show at least one feature that is shared by two adjacent repeat units.

The number of features in a given pattern can be odd or even. In one embodiment, if the total number of features in a given pattern are equal to an odd number, then the number of shared features are generally equal to an odd number. In another embodiment, if the total number of features in a given pattern are equal to an even number, then the number of shared features in the given pattern are equal to an even number.

The spaced features can have variety of geometries and can exist in one, two or three dimensions or any dimensions therebetween. The spaced features can have similar geometries with different dimensions or can have different geometries with different dimensions. For example, in the FIG. 4A, the spaced features are of a similar shape, with each shape having a different sizes, while in the FIGS. 4B, 4C and 4D, the spaced features have different geometries and different dimensions.

The geometries can be regular (e.g., described by Euclidean mathematics) or irregular (e.g., described by non-Euclidean mathematics). Euclidean mathematics describes those structures whose mass is directly proportional to a characteristic dimension of the spaced feature raised to an integer power (e.g., a first power, a second power or a third power). In one embodiment, the geometries can comprise shapes that are described by Euclidean mathematics such as, for example, lines, triangles, circles, quadrilaterals, polygons, spheres, cubes, fullerenes, or combinations of such geometries.

For example, the FIG. 4A shows that the spaced features are almost elliptical, i.e., the cross-sectional geometry of each feature when viewed from the top-down is similar to that which could be obtained by combining rectangles with semi-circles. Similarly, the FIGS. 4B, 4C and 4D, show features that comprise circles, sections of circles (e.g., semi-circles, quarter-circles), triangles, and the like.

In one embodiment, a repeat unit can be combined with a neighboring repeat unit so as to produce a combination of spaced apart features that have a geometry that is described by Euclidean mathematics. In one embodiment, the spaced features can have irregular geometries that can be described by non-Euclidean mathematics. Non-Euclidean mathematics is generally used to describe those structures whose mass is directly proportional to a characteristic dimension of the spaced feature raised to a fractional power (e.g., fractional powers such as 1.34, 2.75, 3.53, or the like). Examples of geometries that can be described by non-Euclidean mathematics include fractals and other irregularly shaped spaced features.

In one embodiment, spaced features whose geometries can be described by Euclidean mathematics may be combined to produce features whose geometries can be described by non-Euclidean mathematics. In other words, the groupings of features can have dilational symmetry. The fractal dimension can be measured perpendicular to the template surface upon which the features are disposed or may be measured parallel to the template surface upon which the features are disposed. The fractal dimensions are measured in the inter-topographical gaps.

In one embodiment, the fractal dimensions can have fractional powers of about 1.00 to about 3.00, specifically about 1.25 to about 2.25, more specifically about 1.35 to about 1.85 in a plane measured parallel to the surface upon which the features are disposed. In another embodiment, the fractal dimensions can have fractional powers of about 1.00 to about 3.00, specifically about 1.25 to about 2.25, more specifically about 1.35 to about 1.85 in a plane measured perpendicular to the surface upon which the features are disposed.

In yet another embodiment, the fractal dimensions can have fractional powers of about 3.00 to about 4.00, specifically about 3.25 to about 3.95, more specifically about 3.35 to about 3.85 in a plane measured perpendicular to the surface upon which the features are disposed. In other words, the tortuous pathway or the surface of each feature may be textured with features similar to those of the pattern (albeit on a smaller scale), thus creating micro-tortuous pathways and nano-tortuous pathways within the tortuous pathway itself.

In another embodiment, the spaced features may have multiple fractal dimensions in a direction parallel to the surface upon which the features are disposed. The spaced features may be arranged to have 2 or more fractal dimensions, specifically 3 or more dimensions, specifically 4 or more dimensions in a direction parallel to the surface upon which the features are disposed. The fractal dimensions created by the features in a direction from the top to the bottom of the micrograph are 1.444 and 1.519 respectively, while the fractal dimension created by the features in a direction from left to right have dimensions of 1.557. The presence of the texture having multiple fractal dimensions prevents bioadhesion of algae, bacteria, virus, and other organisms.

In yet another embodiment, the spaced features may have multiple fractal dimensions in a direction perpendicular to the surface upon which the features are disposed. The spaced features may be arranged to have 2 or more fractal dimensions, specifically 3 or more dimensions, specifically 4 or more dimensions in a direction parallel to the surface upon which the features are disposed.

The tortuous pathway on the template may be defined by a sinusoidal function, a spline function, a polynomial function, or the like. The tortuous pathway generally exists between a plurality of groupings of spaced features and may occasionally be interrupted by the existence of a feature or by contact between two features. The frequency of the intersection between the tortuous pathway and the spaced feature may be periodic or aperiodic. In one embodiment, the tortuous pathway may have a periodicity to it. In another embodiment, the tortuous pathway may be aperiodic. In one embodiment, two or more separate tortuous pathways never intersect one another.

The tortuous pathway on the template can have a length that extends over the entire length of the surface upon which the pattern is disposed, if the features that act as obstructions in the tortuous pathway are by-passed. The width of the tortuous pathway as measured between two adjacent features of two adjacent patterns are about 10 nanometers to about 500 micrometers, specifically about 20 nanometers to about 300 micrometers, specifically about 50 nanometers to about 100 micrometers, and more specifically about 200 nanometers to about 50 micrometers.

The spaced features on a template have linear pathways or channels between them. In one embodiment, the spaced features can have a plurality of linear pathways or a plurality of channels between them.

It is to be noted that the texture may be different from that disclosed above. For example, a random texture which comprises a combination of various geometries of differing sizes may also be manufactured in the manner detailed herein. The geometries may include 3-sided objects, 4-sided objects, polygons, circles, ellipses, or the like, or a combination thereof. The sides that connect the vertices of the foregoing objects may be linear or curvilinear.

As detailed above, the template is soluble in a solvent. The solvent may be an organic solvent or an aqueous solvent. The solvent may be in the form of a liquid, a vapor, or a combination thereof. Supercritical and/or superheated fluids may also be used. Aqueous solvents are preferred. Liquid carbon dioxide is also preferred. Solvents that can be combined with water to form a co-solvent that can dissolve the template are desirable.

It is desirable to use a solvent or a co-solvent that can dissolve the template at room temperature. Solvents and co-solvents that can dissolve the template at elevated temperatures may also be used. For example, water may be used at temperatures of 32 to 211° F. Steam at temperatures of 212° F. or greater may also be used to dissolve the template. It is generally desirable to use a solvent that can dissolve the template without dissolving or damaging the surface that has been textured by the template.

Liquid aprotic polar solvents such as propylene carbonate, ethylene carbonate, butyrolactone, acetonitrile, benzonitrile, nitromethane, nitrobenzene, sulfolane, dimethylformamide, N-methylpyrrolidone, or the like, or combinations thereof are generally desirable for dissolving the template. Polar protic solvents such as, water, methanol, acetonitrile, nitromethane, ethanol, propanol, isopropanol, butanol, or the like, or combinations thereof may be used. Other non-polar solvents such a benzene, toluene, methylene chloride, carbon tetrachloride, hexane, diethyl ether, tetrahydrofuran, or the like, or combinations thereof may also be used to dissolve the template. Examples of preferred solvents are water, alcohols, tetrahydrofuran, acetone, or combinations thereof. Superheated and supercritical fluids may also be used to dissolve/degrade the template.

In an embodiment, the solvent may contain an acid or base to degrade or disrupt some of the chemical bonds of the template in addition to dissolving the material of the template.

The template containing the features disclosed herein is a disposable template. It can be easily manufactured in large quantities and exported for use to another location. It may be manufactured from a polymer that is environmentally friendly and can be washed off after use using a solvent such as water that is also environmentally friendly. Because the template is manufactured from a flexible, light weight material, it can be used on convoluted surfaces and surfaces having multiple shapes and dimensions.

In one embodiment, the template may be used to texture the surface of a convoluted article using vacuum forming. In a vacuum forming, the template is disposed along the surfaces of a cavity wall. The cavity has the shape that the convoluted article will have after it is vacuum formed. A thermoplastic or thermosetting resin in the form of a sheet of plastic is heated to a forming temperature, and stretched onto the mold surface and forced against the mold by a vacuum. Relatively deep parts can be formed if the formable sheet is mechanically or pneumatically stretched prior to bringing it into contact with the mold surface and applying vacuum. When the thermoplastic resin contacts the template located at the mold surface, the texture is imparted to the article surface.

After the article is textured via vacuum forming, it is washed with a solvent that dissolves the template. The article may then be dried and used for its intended purpose.

In another embodiment, the template may be used in an injection molding or blow molding operation to texture the surface of the article. Because the template is flexible it can be used in mold walls having complicated shapes. A heated thermoplastic or thermosetting resin is injected into the mold and contacts the template that lies along the mold walls. During this contact, the texture is transferred to the article surface. The article is then removed from the mold and subjected to washing with a suitable solvent to remove the template from the article.

When the template is used in operations such as vacuum forming, injection molding, thermoforming or blow molding, it is desirable for the template to have a flow temperature that is higher than the flow temperature of the thermoplastic or thermosetting resin. This ensures that the template will not melt during the forming operation. It is also desirable that the temperature of the solvent used to wash the textured article can dissolve the template but not damage the article. In other words, the dissolution temperature of the template should not produce any damage to the textured article.

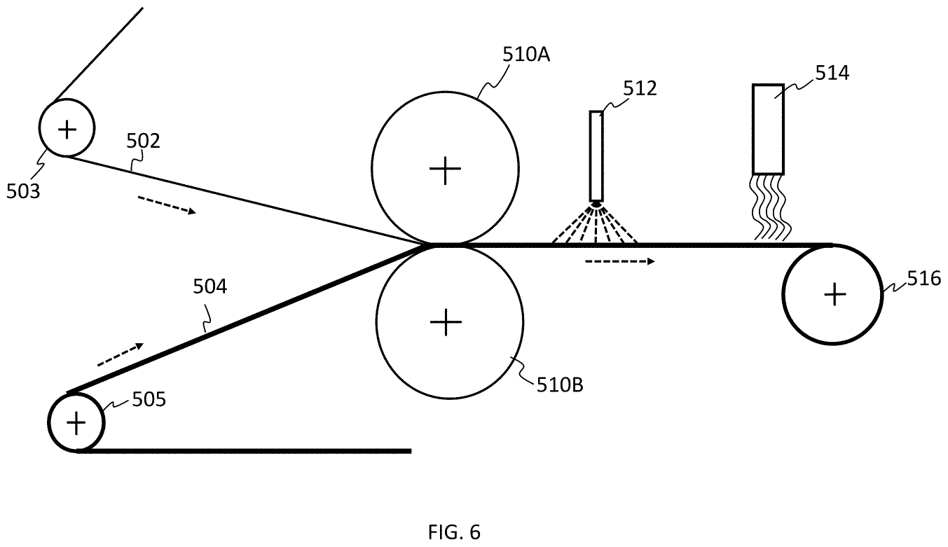

In another embodiment, the template may be used to texture an article surface in a roll mill. This is depicted in the FIG. 6, where the flexible template 502 is used to texture one surface of an article 504. In this exemplary embodiment, the article 504 is a film. The template 502 is wound round a first feed roller 503 while the article 504 is wound round a second feed roller 505. Both the template 502 and the article 504 are simultaneously fed to pair of nip rolls 510A and 510B. The textured surface of the template contacts the article surface in the nip. The nip rolls operate at an elevated pressure and temperature. The roll temperature is effective to soften the surface of the article so that it can be imprinted with the texture from the template. It is desirable for the roll temperature to be below the flow temperature of the template. In short, the flow temperature of the article is lower than the flow temperature of the template.

After imprinting the texture on the article surface, the template along with the article travel together towards the first washer 512. The first washer 512 ejects a solvent and/or a degradant (such as an acid or base) onto the films. The solvent solubilizes the template and washes it away from the textured article. A combination of forced air from a blower 514 along with heat (not shown) may be used to dry the article. While the FIG. 6 shows only one washer and one blower, a plurality of washers and blowers (inclined at different angles) may be used to wash away the template and dry the article. The article now devoid of the template may be wound around another roller 516.

In another embodiment, the template may be used to decorate the article in addition to texturing it. For example, if a template comprises a copolymer that contains two domains—a first domain that is soluble in the solvent that emanates from the washer 512 and a second domain that is incompatible with the solvent, then when the template is subjected to dissolution, the incompatible domains will be left behind on the textured article. The incompatible domains may be referred to as template residue.

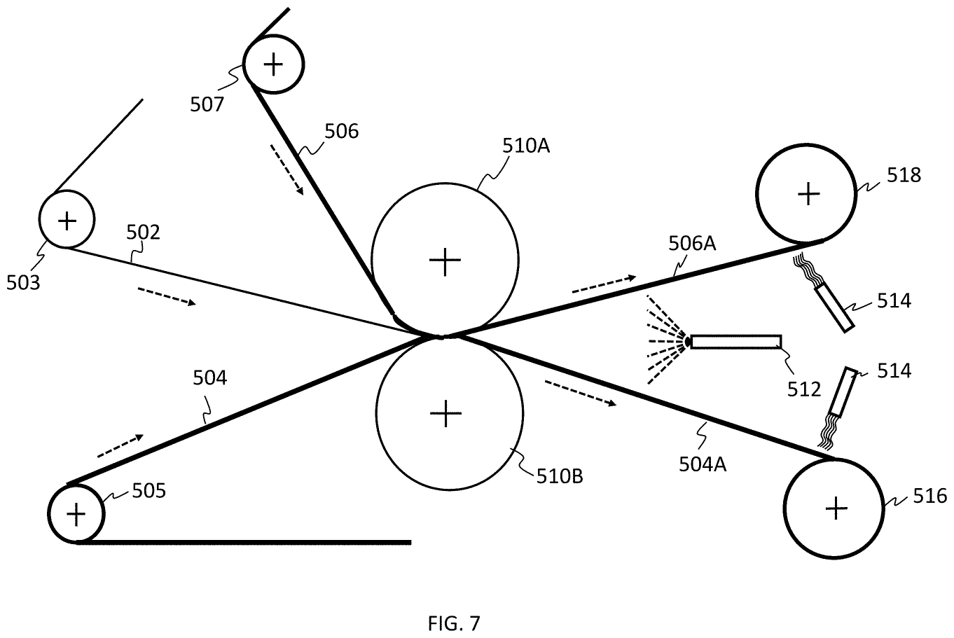

In another embodiment, depicted in the FIG. 7, the template 502 may be used to texture two articles 504, 506 simultaneously. The template 502 is wound round a first feed roller 503 while the first article 504 is wound round a second feed roller 505 and the second article 506 is wound round a third feed roller 507. The template 502 and the articles 504 and 506 are simultaneously fed to pair of nip rolls 510A and 510B. Each surface of the template 502 is textured and contacts at least one surface of each article 504 and 506. The template is sandwiched between the articles and the combination is fed to the nip rollers 510A and 510B. Upon emanating from the nip rollers 510A and 510B, the articles that form the sandwich are separated. The first textured article 504A and the second textured article 506A are wound around separate rollers 516 and 518 respectively. At the point of separation, the washer 512 is used to solubilize the template and to remove it from contact with the textured articles 504A and 506A. The textured articles wound round the separate rollers 516 and 518 are devoid of the template. Forced air from a blower 514 along with heat (not shown) may be used to dry the articles prior to being wound around the rollers 516 and 518.

In this manner multiple articles may be textured. In addition, multiple surfaces of a single article or multiple surfaces of multiple articles may be textured in this manner.

In yet another embodiment, in another manner of using the template, a layer of paint or a coating containing a polymer or a deformable material (e.g., a wax, a curable material such as epoxy) may be disposed on a surface that is to be textured. The layer of paint, polymer, wax, deformable material, or the like, may be referred to as a coating and is in liquid form. After applying the coating layer on the surface, a template is brought into contact with the surface. The template is depressed against the coating for a desirable period during which solidification of the coating takes place. The solidification may occur via evaporation of solvents, curing of the polymer (via an elevated temperature, or because the coating is subjected to electromagnetic radiation such as ultraviolet radiation, microwave radiation, infrared radiation, electron beam radiation) and so on. After the coating has solidified, the template may be dissolved by washing it off the coating. The resulting coating will have a negative image of the textured surface disposed therein.

In summary, the method comprises disposing a liquid coating upon a substrate; disposing upon the coating a template; where the template comprises a soluble polymer that has a texture disposed thereon; where the texture comprises a pattern comprising a first plurality of spaced features; the spaced features arranged in a plurality of groupings; the spaced features within a grouping being spaced apart at an average distance of about 1 nanometer to about 500 micrometers; each feature having a surface that is substantially parallel to a surface on a neighboring feature; each feature being separated from its neighboring feature; and wherein the groupings of features being arranged with respect to one another so as to define a tortuous pathway; where the template is in the form of a free-standing film that has a maximum thickness of 1.5 millimeters and a minimum thickness that is no greater than 40 percent of the maximum thickness; where the surface area of the textured surface is at least greater than 10 cm²; solidifying the coating; and dissolving the template. The solidifying the coating is accomplished via curing or drying.

In an embodiment, a coating of paint or polymer can be applied to an existing product and then textured as detailed above using the template. Recycled products can also be treated in this manner.

The template may be bounded in a protective film (e.g., a silicone film or a polyolefin film) that can prevent it from oxidation and water vapor damage and transported to the site where it is used.

The template and the materials used therein may be exemplified by the following non-limiting example.

### Example

This example was conducted to demonstrate the use of a water soluble polymer in preparing a template from which a given texture can be transferred.

In this example, a polyvinylalcohol commercially available as Sulky Super Solvy water soluble stabilizer film roll was disposed on a substrate that contained a texture similar to that seen in the FIG. 5. The texture has dimensions that could be represented by +2SK2x2. The polyvinylalcohol in the form of a film is disposed on the textured surface of the substrate.

The film is then pressed onto the substrate at an elevated temperature. A hot roll may be used for pressing the polyvinylalcohol film onto the substrate. The temperature of the hot roll is 190° C. A heated iron may be used to achieve the same result.

Upon pressing the film on to the textured substrate at an elevated temperature it flows into the crevices of the substrate. A mirror image of the textured substrate is imprinted onto the surface of the polyvinylalcohol film that contacts the textured surface.

The heated film is then cooled and removed from the substrate. It may now be used as a template to texture another surface.

While the invention has been described with reference to some embodiments, it will be understood by those skilled in the art that various changes may be made and equivalents may be substituted for elements thereof without departing from the scope of the invention. In addition, many modifications may be made to adapt a particular situation or material to the teachings of the invention without departing from essential scope thereof. Therefore, it is intended that the invention not be limited to the particular embodiments disclosed as the best mode contemplated for carrying out this invention, but that the invention will include all embodiments falling within the scope of the appended claims.

1. A method of using a template for texturing a surface comprising:
contacting an article surface with a template; where the template comprises a soluble polymer that has a texture disposed thereon; where the texture comprises a pattern comprising a first plurality of spaced features; the spaced features arranged in a plurality of groupings; the spaced features within a grouping being spaced apart at an average distance of about 1 nanometer to about 500 micrometers; each feature having a surface that is substantially parallel to a surface on a neighboring feature; each feature being separated from its neighboring feature; and wherein the groupings of features being arranged with respect to one another so as to define a tortuous pathway; where the template is in the form of a free-standing film that has a maximum thickness of 1.5 millimeters and a minimum thickness that is no greater than 40 percent of the maximum thickness; where the surface area of the textured surface is at least greater than 10 cm², and
washing the article surface with a solvent that dissolves the template.

2. The method of claim 1, wherein the polymer is soluble in water.

3. The method of claim 1, wherein the polymer has a dissolution rate of 0.5 to 10 grams per minute in an effective solvent.

4. The method of claim 1, wherein the polymer is a linear thermoplastic amorphous polymer or a crosslinked polymer.

5. The method of claim 1, wherein the polymer is selected from the group consisting of polyvinylalcohol, polyacrylamide, polyhexamethylcellulose, polyhexaethylcellulose, polyethyleneimine, polyvinylpyrrolidone, polyamidoamine, polyethylene glycol, or a combination thereof.

6. The method of claim 1, wherein the polymer is a copolymer of at least one of polyvinylalcohol, polyacrylamide, polyhexamethylcellulose, polyhexaethylcellulose, polyethyleneimine, polyethylene glycol, polyvinylpyrrolidone, or polyamidoamine.

7. The method of claim 1, wherein the plurality of spaced features are projected into a surface of the template.

8. The method of claim 1, wherein the groupings of features are arranged with respect to one another so as to define a linear pathway or a plurality of channels.

9. The method of claim 1, wherein the tortuous pathway is defined by a sinusoidal curve or by a spline function.

10. The method of claim 1, wherein the texture is disposed on opposing surfaces of the template.

11. The method of claim 10, wherein a texture on a surface of the template that is opposed to the surface that contacts the article is inclined at an angle with regard to the texture that is imparted to the article.

12. The method of claim 1, wherein the soluble polymer is polyvinylalcohol.

13. The method of claim 1, wherein the solvent is an aqueous solvent.

14. The method of claim 1, wherein the solvent is water.

15. The method of claim 1, wherein the soluble polymer is not compatible with water.

16. The method of claim 1, wherein the contacting of the article surface with the template occurs under a vacuum.

17. The method of claim 1, wherein the contacting of the article surface with the template occurs under a pressure.

18. The method of claim 1, wherein the template simultaneously contacts an additional article surface

19. The method of claim 1, further comprising leaving behind a template residue on the article surface; and wherein the template residue is insoluble in the solvent.

20. A method comprising:
disposing a liquid coating upon a substrate;
disposing upon the coating a template; where the template comprises a soluble polymer that has a texture disposed thereon; where the texture comprises a pattern comprising a first plurality of spaced features; the spaced features arranged in a plurality of groupings; the spaced features within a grouping being spaced apart at an average distance of about 1 nanometer to about 500 micrometers; each feature having a surface that is substantially parallel to a surface on a neighboring feature; each feature being separated from its neighboring feature; and wherein the groupings of features being arranged with respect to one another so as to define a tortuous pathway; where the template is in the form of a free-standing film that has a maximum thickness of 1.5 millimeters and a minimum thickness that is no greater than 40 percent of the maximum thickness; where the surface area of the textured surface is at least greater than 10 cm²;
solidifying the coating; and
dissolving the template.

21. The method of claim 20, where the solidifying the coating is accomplished via curing.

22. The method of claim 20, where the solidifying the coating is accomplished via drying.
